(19) United States
(12) Patent Application Publication
(10) Pub. No.: US 2002/0109971 A1
(43) Pub. Date: Aug. 15, 2002

(54) Add-on cable feed-through device for computer chassis

(75) Inventor: David E. Gilley, Wellesley, MA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Force Computers, Inc.

(21) Appl. No.: 09/788,178

(22) Filed: Feb. 15, 2001

Related U.S. Application Data
(60) Provisional application No. 60/227,136, filed on Aug. 22, 2000.

(51) Int. Cl. G06F 1/16; H05K 5/00

(52) U.S. Cl. 361/724; 361/683

(57) ABSTRACT

A computer chassis comprises a main chassis housing including a through opening from a front to a rear of the housing. A front cable feed-through assembly is detachably coupled with the main chassis and inserted into the through opening from the front of the housing. The front cable feed-through assembly includes at least one front cable feed-through slot. A rear cable feed-through assembly is detachably coupled with the main chassis and inserted into the through opening from the rear of the housing. The rear cable feed-through assembly includes at least one rear cable feed-through slot. The rear cable feed-through assembly is detachably connected to the front cable feed-through assembly inside the main chassis housing. The housing includes an upper card guide at a top of the through opening and a lower card guide at a bottom of the through opening. The front and rear cable feed-through assemblies each include a top sliding edge slidably guided into the through opening by the upper card guide and a bottom sliding edge slidably guided into the through opening by the lower card guide.

This application is based on and claims the benefit of U.S. Provisional Patent Application No. 60/227,136, filed Aug. 22, 2000, the entire disclosure of which is incorporated herein by reference.

### BACKGROUND OF THE INVENTION

This invention relates generally to an electronic component system and, more particularly, to an add-on cable feed-through device for use within a computer housing such as a rack-mounted Eurocard computer chassis or enclosure.

A computer chassis or enclosure may employ a center-mounted backplane or midplane with both front and rear plug-in I/O boards. These boards plug into high density pin connectors mounted on both sides of the backplane. A backplane typically includes a series of multiway pins or sockets wired in parallel and connected to the buses of the computer to enable the computer to communicate with peripherals, such as disk drives, boards, controllers, etc. The backplane typically is secured with screws at its top and bottom backside to horizontal support members within the chassis.

The computer chassis or enclosure typically allows external I/O cables to be connected to either the front or the rear of the unit's I/O boards. Some computer chassis or enclosures have a passageway or cable feed-through designed and built into the unit for feeding the I/O cables through the unit. For those without the built-in cable feed-through feature, there is no simple, clean way of feeding the I/O cables back to the front from the rear or to the rear from the front. In some computer chassis or enclosures, the I/O cables could be dressed above or below the unit, but it would require the user to sacrifice valuable rack space.

### SUMMARY OF THE INVENTION

The present invention is directed to a device that provides a passageway to dress external I/O cables, through a computer enclosure or chassis, either front to rear or rear to front. The device advantageously maintains electromagnetic compatibility (EMC) tightness for computer chassis and enclosure. The device is configured to attach to any unused front and rear plug-in slots which do not have a backplane or midplane between the plug-ins, and allows the cables to pass directly through the enclosure or chassis in an EMC tight channel. The device allows an enclosure without a built-in cable feed-through feature to be easily upgraded. The device allows cables to pass through the enclosure rather than use valuable rack space above or below the enclosure for cable feed through.

In accordance with an aspect of the present invention, a computer chassis comprises a main chassis housing including a through opening from a front to a rear of the housing. A front cable feed-through assembly is detachably coupled with the main chassis and inserted into the through opening from the front of the housing. The front cable feed-through assembly includes at least one front cable feed-through slot. A rear cable feed-through assembly is detachably coupled with the main chassis and inserted into the through opening from the rear of the housing. The rear cable feed-through assembly includes at least one rear cable feed-through slot. The rear cable feed-through assembly is detachably connected to the front cable feed-through assembly inside the main chassis housing.

In some embodiments, the rear cable feed-through assembly includes a plurality of rear interlocking members. The front cable feed-through assembly includes a plurality of front interlocking members which interlock with the plurality of rear interlocking members to form the electromagnetic compatibility connection. The main chassis housing includes a top horizontal member and a bottom horizontal member. The front cable feed-through assembly includes a front panel which is coupled to the top horizontal member and the bottom horizontal member to form a secure and electromagnetic compatibility connection in the front of the main chassis housing. The rear cable feed-through assembly includes a rear panel which is coupled to the top horizontal member and the bottom horizontal member to form a secure and electromagnetic compatibility connection in the rear of the main chassis housing.

In specific embodiments, the front cable feed-through assembly includes a front panel having at least one front cable feed-through slot, a front left side panel coupled to the front panel, and a front right side panel coupled to the front panel. The front right side panel is coupled with and spaced from the front left side panel. The rear cable feed-through assembly includes a rear panel having at least one rear cable feed-through slot, a rear left side panel coupled to the rear panel, and a rear right side panel coupled to the rear panel. The rear right side panel is coupled with and spaced from the rear left side panel. The front right side panel interlocks with the rear right side panel, and the front left side panel interlocks with the rear left side panel. In a specific embodiment, the front right side panel and rear right side panel include overlapping right fingers which interlock with each other. The front left side panel and rear left side panel include overlapping left fingers which interlock with each other.

In accordance with another aspect of the invention, a computer chassis comprises a main chassis housing including a through opening from a front to a rear of the housing. The housing includes an upper card guide at a top of the through opening and a lower card guide at a bottom of the through opening. A cable feed-through assembly is detachably coupled with the main chassis and inserted into the through opening. The cable feed-through assembly includes at least one front cable feed-through slot at the front of the housing and at least one rear feed-through slot at the rear of the housing. The cable feed-through assembly includes a top sliding edge slidably guided into the through opening by the upper card guide and a bottom sliding edge slidably guided into the through opening by the lower card guide.

In some embodiments, the cable feed-through assembly includes a front panel having at least one front feed-through slot and a rear panel having at least one rear feed-through slot. The cable feed-through assembly includes side panels disposed inside the through opening of the main chassis housing and being connected with the front panel and the rear panel. The side panels of the cable feed-through assembly are connected with the front panel and the rear panel by at least one tongue-and-groove connection.

Another aspect of the invention is directed to a cable feed-through device to be detachably added onto a computer chassis housing which includes a through opening from a front to a rear of the housing and which includes an upper card guide at a top of the through opening and a lower card guide at a bottom of the through opening. The cable feed-through device comprises a front cable feed-through assembly including a top sliding edge and a bottom sliding edge. The front cable feed-through assembly is configured to be inserted into the through opening from the front of the housing with the top sliding edge guided by the upper card guide and the bottom sliding edge guided by the lower card guide. The front cable feed-through assembly includes at least one front cable feed-through slot. A rear cable feed-through assembly includes a top sliding edge and a bottom sliding edge. The rear cable feed-through assembly is configured to be inserted into the through opening from the rear of the housing with the top sliding edge guided by the upper card guide and the bottom sliding edge guided by the lower card guide. The rear cable feed-through assembly includes at least one rear cable feed-through slot. The rear cable feed-through assembly is to be detachably connected to the front cable feed-through assembly inside the main chassis housing.

### BRIEF DESCRIPTION OF THE DRAWINGS

FIG. 1 is a perspective view of a computer chassis illustrating an add-on cable feed-through device in accordance with an embodiment of the present invention;

FIG. 2 is an exploded perspective view of the front half of the add-on cable feed-through device of FIG. 1;

FIG. 3 is a perspective view of the front and rear halves of the add-on cable feed-through device of FIG. 1 in unassembled form; and

FIG. 4 is a perspective view of the assembled add-on cable feed-through device of FIG. 1.

### DESCRIPTION OF THE SPECIFIC EMBODIMENTS

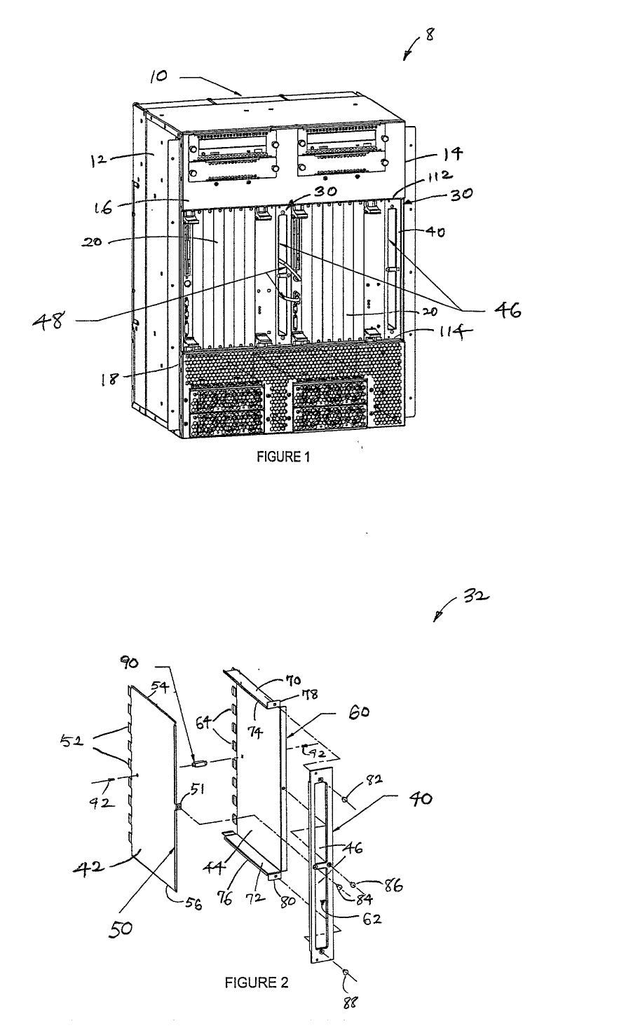

FIG. 1 shows a computer enclosure or chassis 8 having a main chassis housing 10 that includes side panels 12, 14 as well as top and bottom horizontal members 16, 18. Disposed inside the main chassis housing 10 are two backplanes 20 which are mounted in the main chassis housing 10. FIG. 1 shows two add-on cable feed-through devices 30 each providing a passageway to dress external I/O cables through the computer chassis, from front to rear, or from rear to front.

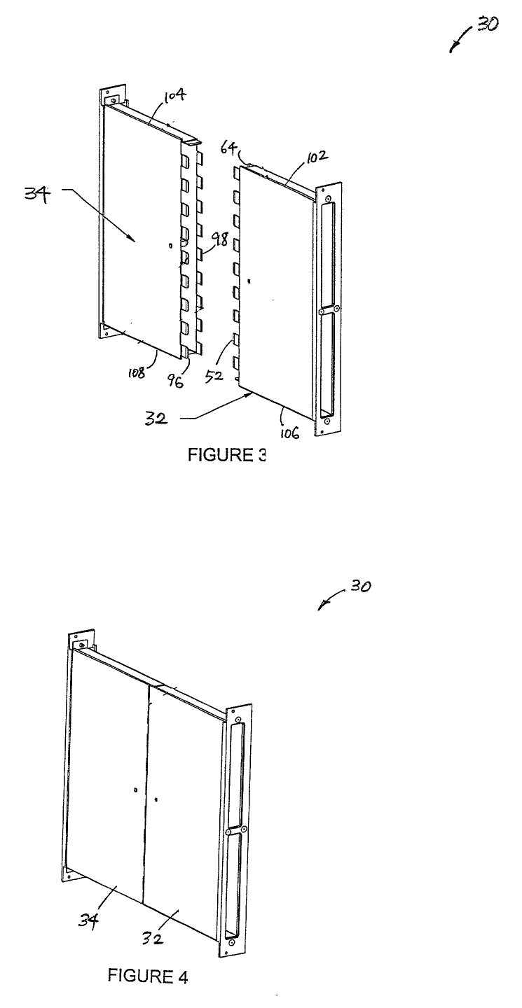

As more clearly seen in FIGS. 2-4, the feed-through device 30 includes a front half assembly 32 and a rear half assembly 34. As best seen in FIG. 2, the front assembly 32 includes a front panel 40, a left side panel 42, and a right side panel 44. The front panel 40 includes one or more openings 46 to allow feed-through of cables 48 (FIG. 1). The left side panel 42 desirably includes at the front edge double angled surfaces 50 to provide improved contact with the front panel 40, and an apertured tab 51. At the rear edge of the left side panel 42 are a plurality of fingers 52. Interlocking members 54, 56 are provided respectively at the top and bottom edges of the left side panel 42. The right side panel 44 includes at the front a side panel edge 60 which locks into a groove 62 on the rear side of the front panel 40. At the rear edge are a plurality of fingers 64. Top and bottom panels 70, 72 are provided respectively along the top and bottom edges of the right side panel 44, and may be integrally formed as a single piece. The top panel 70 includes an interlocking member 74 for interlocking with the top interlocking member 54 of the left side panel 42, for instance, by a tongue and groove connection. The bottom panel 72 includes an interlocking member 76 for interlocking with the bottom interlocking member 56 of the left side panel 42, for instance, by a tongue and groove connection. The top panel 70 has a top panel edge 78, and the bottom panel 72 has a bottom panel edge 80.

The front panel 40 may be simply constructed from a standard extruded front filler panel reworked with machined openings 46 in the panel. The side panels 42, 44 may be constructed from two sheet metal panels interlocked or fastened to each other and then interlocked or fastened to the front panel 40. A fastener 82 connects the front panel 40 to the top panel edge 78 of the top panel 70. A fastener 84 connects the front panel 40 to the apertured tab 51 of the left side panel 42. A fastener 86 connects the front panel 40 to the front panel edge 60 of the right side panel 44. A fastener 88 connects the front panel 40 to the bottom panel edge 80 of the bottom panel 72. Near the rear edges of the left and right side panels 42, 44, a spacer 90 is disposed between the panels 42, 44 to accommodate securing screws 92 for coupling the side panels 42, 44 together.

As shown in FIG. 3, the rear assembly 34 is similar to the front assembly 32. The rear assembly 34 includes left fingers 96 for interlocking with overlapping left fingers 52 of the front assembly 32, and includes right fingers 98 for interlocking with overlapping right fingers 64 of the front assembly 32. The interlocking fingers advantageously provide EMC connection between the front and rear assemblies 32, 34, as seen in FIG. 4.

As shown in FIGS. 3 and 4, the front assembly 32 includes a top sliding edge 102 formed by the top interlocking members 54, 74, and the rear assembly 34 has a similar top sliding edge 104. The front assembly 32 includes a bottom sliding edge 106 formed by the bottom interlocking members 56, 76, and the rear assembly 34 has a similar bottom sliding edge 108. The top and bottom sliding edges slide into top and bottom chassis card guides 112, 114, respectively, of the chassis 10, as shown in FIG. 1. These slide edges are formed to represent a plug-in's card edge. Typically, the front assembly 32 slides into the plug-in slot card guides 112, 114 from the front, while the rear assembly 34 slides in from the rear. At the midpoint of the enclosure 10, the front and rear assemblies 32, 34 interconnect with the overlapping fingers forming an EMC tight connection. As seen in FIG. 1, the front panel 40 of the front assembly 32 extends between the top and bottom horizontal members 16, 18 of the enclosure 10 to form EMC tight seals in the front. Similarly, the rear panel of the rear assembly 34 extends between the top and bottom horizontal members 16, 18 of the enclosure 10 to form EMC tight seals in the rear.

The add-on cable feed-through device 30 is configured to attach to any unused front and rear plug-in slots which do not have a backplane or midplane between the plug-ins and to allow the cables 48 to pass directly through the enclosure or chassis 10 in an EMC tight channel. The width of the cable feed-through openings 46 is only limited by the width of the front panel 40 and the width of the opening between backplanes 20. The cables 48 pass through the enclosure 10 via the device 30 instead of using valuable rack space above or below the enclosure 10. The device 30 allows an enclosure 10 without a built-in cable feed-through feature to be easily upgraded saving the user time and expense of developing an enclosure with the feature built in.

The above-described arrangements of apparatus and methods are merely illustrative of applications of the principles of this invention and many other embodiments and modifications may be made without departing from the spirit and scope of the invention as defined in the claims. For instance, the tongue and groove connections may be replaced by other types of connections. The overlapping finger connections may be replaced by other types of connections. The scope of the invention should, therefore, be determined not with reference to the above description, but instead should be determined with reference to the appended claims along with their full scope of equivalents.

What is claimed is:

1. A computer chassis comprising:
a main chassis housing including a through opening from a front to a rear of the housing;
a front cable feed-through assembly detachably coupled with the main chassis and inserted into the through opening from the front of the housing, the front cable feed-through assembly including at least one front cable feed-through slot; and
a rear cable feed-through assembly detachably coupled with the main chassis and inserted into the through opening from the rear of the housing, the rear cable feed-through assembly including at least one rear cable feed-through slot, the rear cable feed-through assembly detachably connected to the front cable feed-through assembly inside the main chassis housing.

2. The computer chassis of claim 1 wherein the rear cable feed-through assembly is detachably connected to the front cable feed-through assembly to form an electromagnetic compatibility connection.

3. The computer chassis of claim 2 wherein the rear cable feed-through assembly includes a plurality of rear interlocking members, and wherein the front cable feed-through assembly includes a plurality of front interlocking members which interlock with the plurality of rear interlocking members to form the electromagnetic compatibility connection.

4. The computer chassis of claim 1 wherein the main chassis housing includes a top horizontal member and a bottom horizontal member, and wherein the front cable feed-through assembly and the rear cable feed-through assembly are disposed between the top and bottom horizontal members.

5. The computer chassis of claim 4 wherein the front cable feed-through assembly includes a front panel which is coupled to the top horizontal member and the bottom horizontal member to form an electromagnetic compatibility connection in the front of the main chassis housing.

6. The computer chassis of claim 4 wherein the rear cable feed-through assembly includes a rear panel which is coupled to the top horizontal member and the bottom horizontal member to form an electromagnetic compatibility connection in the rear of the main chassis housing.

7. The computer chassis of claim l wherein the front cable feed-through assembly includes a front panel having the at least one front cable feed-through slot, a front left side panel coupled to the front panel, and a front right side panel coupled to the front panel, the front right side panel being coupled with and spaced from the front left side panel.

8. The computer chassis of claim 7 wherein the rear cable feed-through assembly includes a rear panel having the at least one rear cable feed-through slot, a rear left side panel coupled to the rear panel, and a rear right side panel coupled to the rear panel, the rear right side panel being coupled with and spaced from the rear left side panel; wherein the front right side panel interlocks with the rear right side panel, and the front left side panel interlocks with the rear left side panel.

9. The computer chassis of claim 8 wherein the front right side panel and rear right side panel include overlapping right fingers which interlock with each other, and wherein the front left side panel and rear left side panel include overlapping left fingers which interlock with each other.

10. The computer chassis of claim 7 wherein the front cable feed-through assembly includes a spacer disposed between and spacing apart the front right side panel and the front left side panel.

11. A computer chassis comprising:
a main chassis housing including a through opening from a front to a rear of the housing, the housing including an upper card guide at a top of the through opening and a lower card guide at a bottom of the through opening; and
a cable feed-through assembly detachably coupled with the main chassis and inserted into the through opening, the cable feed-through assembly including at least one front cable feed-through slot at the front of the housing and at least one rear feed-through slot at the rear of the housing, the cable feed-through assembly including a top sliding edge slidably guided into the through opening by the upper card guide and a bottom sliding edge slidably guided into the through opening by the lower card guide.

12. The computer chassis of claim 1 1 wherein the cable feed-through assembly includes a front panel having the at least one front feed-through slot and a rear panel having the at least one rear feed-through slot.

13. The computer chassis of claim 12 wherein the front panel is connected to the front of the main chassis housing to form an electromagnetic compatibility connection, and the rear panel is connected to the rear of the main chassis housing to form an electromagnetic compatibility connection.

14. The computer chassis of claim 12 wherein the cable feed-through assembly includes side panels disposed inside the through opening of the main chassis housing and being connected with the front panel and the rear panel.

15. The computer chassis of claim 14 wherein the side panels of the cable feed-through assembly are connected with the front panel and the rear panel by at least one tongue-and-groove connection.

16. A cable feed-through device to be detachably added onto a computer chassis housing which includes a through opening from a front to a rear of the housing and which includes an upper card guide at a top of the through opening and a lower card guide at a bottom of the through opening, the cable feed-through device comprising:
a front cable feed-through assembly including a top sliding edge and a bottom sliding edge, the front cable feed-through assembly being configured to be inserted into the through opening from the front of the housing with the top sliding edge guided by the upper card guide and the bottom sliding edge guided by the lower card guide, the front cable feed-through assembly including at least one front cable feed-through slot; and
a rear cable feed-through assembly including a top sliding edge and a bottom sliding edge, the rear cable feed-through assembly being configured to be inserted into the through opening from the rear of the housing with the top sliding edge guided by the upper card guide and the bottom sliding edge guided by the lower card guide, the rear cable feed-through assembly including at least one rear cable feed-through slot, the rear cable feed-through assembly to be detachably connected to the front cable feed-through assembly inside the main chassis housing.

17. The cable-feed-through device of claim 16 wherein the rear cable feed-through assembly includes a plurality of rear interlocking members, and wherein the front cable feed-through assembly includes a plurality of front interlocking members which interlock with the plurality of rear interlocking members.

18. The cable feed-through device of claim 16 wherein the front cable feed-through assembly includes a front panel having the at least one front feed-through slot, and wherein the rear cable feed-through assembly includes a rear panel having the at least one rear feed-through slot.

19. The cable feed-through device of claim 18 further comprising means for connecting the front panel to the front of the main chassis housing to form an electromagnetic compatibility connection and connecting the rear panel to the rear of the main chassis housing to form an electromagnetic compatibility connection.

20. The cable feed-through device of claim 18 wherein the front cable feed-through assembly includes a front left side panel and a front right side panel coupled to the front panel, wherein the rear cable feed-through assembly includes a rear left side panel and a rear right side panel coupled to the rear panel, and wherein the front right side panel and rear right side panel include overlapping right fingers which interlock with each other, and wherein the front left side panel and rear left side panel include overlapping left fingers which interlock with each other.
